(19) United States
(12) Patent Application Publication
(10) Pub. No.: US 2016/0094012 A1
(43) Pub. Date: Mar. 31, 2016

(54) LASER BEAM GENERATING DEVICE AND METHOD FOR ADJUSTING A WAVELENGTH OF A LASER BEAM

(71) Applicant: DirectPhotonic Industries GmbH, Berlin (DE)

(72) Inventors: FABIO FERRARIO, BERLIN (DE); BASTIAN KRUSCHKE, BERLIN (DE); HARO FRITSCHE, BERLIN (DE); RALF KOCH, LINDINGO (SE)

(73) Assignee: DirectPhotonic Industries GmbH, Berlin (DE)

(21) Appl. No.: 14/711,188

(22) Filed: May 13, 2015

(30) Foreign Application Priority Data
Apr. 16, 2014 (EP) 14165022.6

(51) Int. Cl. H01S 5/00; H01S 5/022; H01S 5/40

(52) U.S. Cl. CPC H01S 5/0078; H01S 5/4087; H01S 5/0228

(57) ABSTRACT

The current invention concerns a laser beam generating device and a method for adjusting a wavelength of a laser beam.

The current invention addresses the objective of further improving laser beam generation and wavelength adjustment. The current invention particularly allows for simplifying the combination of laser source elements such that they operate at different, but controlled, wavelengths with their beams overlapping.

The laser beam generating device (100) comprises at least one laser source element (11) and an external cavity. The external cavity comprises an output coupler (40) and a periodic filter element (30) arranged between the laser source element (11) and the output coupler (40). The laser beam generating device is characterized in that the laser beam generating device further comprises at least two cut-off filter elements (21, 22) each arranged between the laser source element (11) and the periodic filter element (30).

The current invention concerns a laser beam generating device and a method for adjusting a wavelength of a laser beam.

Laser beam generation commonly involves a laser source element and a cavity. The cavity serves as a resonator for forming standing light waves. The cavity may be formed by additional elements then being called external cavity. A laser source element for such an external cavity may be a laser diode.

An external cavity is advantageous in allowing for arrangement of a wavelength selective element within the cavity thereby achieving a wavelength dependent feedback. The laser source element may such be locked to a specific frequency. Examples of wavelength selective element comprise gratings, e.g. volume Bragg gratings (VBG), and Fabry-Perot-Interferometer (Etalon) as well as combinations thereof.

In a Littrow configuration a diode having a back facet generates a beam which is collimated and then interacts with a diffraction grating. The grating is configured to reflect the 1^{st} diffraction mode back while the 0^{th} diffraction mode forms the output beam. The back facet constitutes the resonator together with the diffraction grating. Adjusting the grating allows for adjusting the laser's wavelength but causes the output beam to pan.

In a Littman configuration the 1^{st} mode is not directly reflected back by the grating but reflected onto a mirror. The mirror then reflects the 1st mode back into the diode. Adjusting the mirror allow for adjusting the laser's wavelength whilst panning of the output beam is avoided.

Daneu V., et al., describe in Opt. Lett., 2000 Mar. 15; 25(6):405-7, a “spectral beam combining of a broad-stripe diode laser array in an external cavity”. The outputs from an 11-element, linear diode laser array with broad stripes have been beam combined into a single beam using a common external cavity containing a grating, which simultaneously forces each array element to operate at a different, but controlled, wavelength and forces the beams from all the elements to overlap and propagate in the same direction. Such combination is also called wavelength multiplexing.

WO2013143862 describes a laser diode with an external volume Bragg grating that can be used for pumping, wherein a coupled resonator of the LD has a Yb:YAG as a laser-active medium, as well as a Fabry-Perot etalon for suppressing spectral components that are not suppressed by the narrow-band VBG.

U.S. Pat. No. 6,876,679 B1 describes multiplexing of incoherent laser beams by means of filters and a Bragg grating. EP 1 850 431 A1 teaches changing the inclination of an etalon with respect to incident light for changing wavelength of etalon peaks.

### SUMMARY OF THE INVENTION

The current invention addresses the objective of further improving laser beam generation and wavelength adjustment. The current invention particularly allows for simplifying the combination of laser source elements such that they operate at different, but controlled, wavelengths with their beams overlapping and propagating in the same direction. Hence the current invention allows for stabilizing the wavelength alone as well as for multiplexing and stabilizing in a single embodiment.

This is achieved by the laser beam generating device of claim 1. Advantageous embodiments are specified in the dependent claims.

The laser beam generating device comprises at least one laser source element and an external cavity. The external cavity comprises an output coupler and a periodic filter element arranged, on a light path from the laser source element and the output coupler, between the laser source and the output coupler. The laser beam generating device is characterized in that the laser beam generating device further comprises at least two cut-off filter elements each arranged on the light path between the laser source and the etalon.

Through the use of cut-off filter elements, a band pass filter element is realized in a simple manner which additionally allows for spectral combination of the laser source elements. Through the band pass a single resonance mode of the periodic filter element is fed back into the laser source element. So the laser source element is locked to emission at a peak frequency of the single resonance mode.

In an embodiment, the external cavity may be optimized using a set of optical elements located in the external cavity and choice of the output coupler reflectivity and curvature.

The cut-off filter elements may be long pass-filter elements having different cut-off wavelengths of which each allows radiation of wavelengths longer than a respective cut-off wavelength to pass, and at least reflect radiation of wavelengths shorter than the respective cut-off wavelength. For instance, the at least two long pass filter elements may be cold mirrors. The cold mirrors may comprise dielectric coating layers.

Or, the cut-off filter elements are short pass-filter elements of which each allows radiation of wavelengths shorter than a respective cut-off wavelength to pass, and at least reflect radiation of wavelengths longer than the respective cut-off wavelength. Or, one of the cut-off filter elements is a long pass-filter element and one is a short pass filter element.

The laser source element and the at least two cut-off filter elements may be arranged on the light path such that light of the laser source element is irradiated onto a first of the at least two cut-off filter elements and a reflected part of the irradiated light is reflected by the first cut-off filter element onto a second of the at least two cut-off filter elements through which it is transmitted.

A further laser source element may be comprised by the laser beam generating device said further laser source element being arranged on the light path such that further light of the further laser source element is irradiated onto the second cut-off filter element and reflected by the second cut-off filter element such that it is kept in the cavity.

Then, a further cut-off filter element may be comprised by the laser beam generating device, the further cut-off filter element being arranged, either, on a further light path between the second cut-off filter element and the further laser source element, or, on the light path between the second cut-off filter element and the periodic filter element.

The laser source element and/or the further laser source element may be laser diodes emitting light which diverges in a first direction faster than in a second direction perpendicular to the first direction, the laser diodes and the dichroic mirrors being arranged such that light of the laser diodes is superposed in the first direction.

Then, collimating devices may be comprised by laser beam generating device the collimating devices collimating the light emitted by the laser diodes, the collimating devices collimating in the first direction and in the second direction. The laser diodes may be single emitters. Single emitters may be arranged in an array. Single emitters may be stacked horizontally or vertically.

The periodic filter element may comprise two parallel plates placed spaced apart with air in between wherein sides of the plates facing each other. The plates can be coated to tailor the power reflectivity.

It is further proposed a method according to claim 13 for adjusting a wavelength of a laser beam using the laser beam generating device according to the invention. The method comprises fine adjusting the wavelength by turning the etalon around an axis for varying an incident angle.

The different embodiments of this invention can be combined advantageously with each other.

### BRIEF DESCRIPTION OF THE DRAWINGS

Below, exemplary embodiments of the invention will be described in more detail by help of the figures wherein

FIG. 1 shows a first exemplary embodiment of the laser beam generating device according to the invention;

FIG. 2 schematically shows transmission T in dependency on wavelength lambda of the cut-off filter elements and the periodic filter element of the exemplary embodiment of FIG. 1;

FIG. 3 shows a second exemplary embodiment of the laser beam generating device according to the invention;

FIG. 4 shows a third exemplary embodiment of the laser beam generating device according to the invention;

FIG. 5 shows a fourth exemplary embodiment of the laser beam generating device according to the invention;

FIG. 6 shows a fifth exemplary embodiment of the laser beam generating device according to the invention;

FIG. 7 schematically shows transmission T in dependency on wavelength lambda of the cut-off filter elements and the periodic filter element of the exemplary embodiment of FIG. 6; and

FIG. 8 shows a sixth exemplary embodiment of the laser beam generating device according to the invention.

### DETAILED DESCRIPTION OF THE DRAWINGS

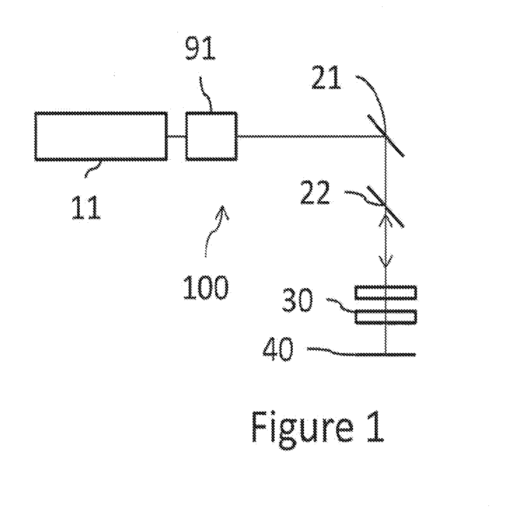

FIG. 1 shows a first exemplary embodiment of the laser beam generating device according to the invention.

The first embodiment comprises a laser source element exemplarily realized by a laser diode 11 and at least two cut-off filter elements exemplarily realized by long pass filter elements 21, 22. The long pass filter elements 21, 22 are arranged such that a portion of the light emitted by the laser diode 11 is reflected by a first of the at least two long pass filter elements 21, 22. The reflected portion comprises wavelengths shorter than a first cut-off wavelength W1. The reflected portion is reflected onto a second of the at least two long pass filter elements 21, 22. Of said portion reflected on the second long pass filter element 22, the second long pass filter element 22 lets pass a transmitted portion onto a periodic filter element exemplarily realized by an etalon 30. The portion let pass comprises wavelengths equal to or longer than a second cut-off wavelength W2 said second cut-off wavelength W2 being shorter than the first cut-off wavelength W1. Light passing through the etalon 30 meets an output coupler 40, also called output mirror, where it is reflected back through the etalon 30 onto the second long pass filter element 22. The back-reflected light is than filtered through the etalon and filters and fed back into the laser source, selecting in this way the emitted wavelength.

In the depicted first exemplary embodiment, there is an optical element 91 located in the external cavity for optimizing performance. But the optical element 91 is optional and this exemplary embodiment of the invention may be realized without, also.

Thus, while the etalon 30 allows for a precise selection of wavelengths, the at least two long pass filter elements 21, 22 realize a band pass filter element having a pass band between the first and the second cut-off wavelengths W1, W2 and selecting one or more of the periodic peaks achievable by the etalon 30.

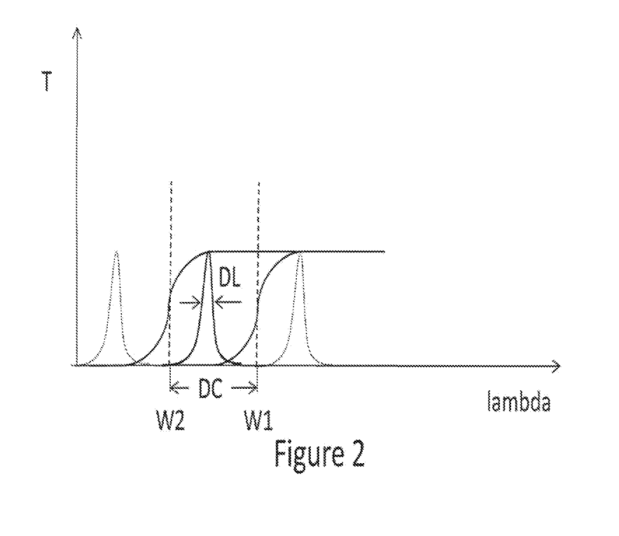

FIG. 2 schematically shows transmission T in dependency on wavelength lambda of the cut-off filter elements and the periodic filter element of the exemplary embodiment of FIG. 1. As exemplarily depicted in FIG. 2, the peak has a peak width DL of the selected mode of the periodic filter element which is about half as wide as the width DC=W1-W2 of the pass band between the first and the second cut-off wavelengths W1, W2. Modes are shown in dotted lines which are suppressed in the feedback by the cut-off filter elements.

This provides a very precise wavelength locking. In addition thereto, light of a second laser source element can be superposed and thus spectrally combined easily.

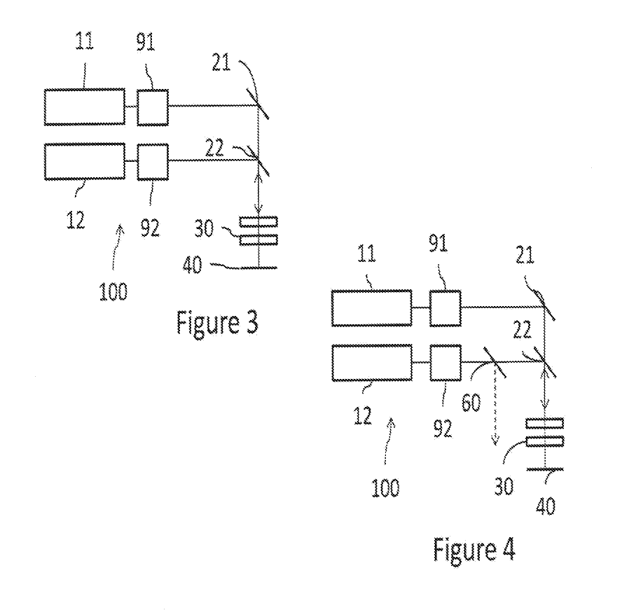

Superposition can be achieved, for instance, by emitting further light of a second laser source element 12 onto the second long pass filter element 22 such that the second long pass filter element 22 reflects onto the etalon 30 a further reflected portion of the further light. This is shown exemplarily in FIG. 3 depicting a second exemplary embodiment of the laser beam generating device according to the invention.

Then, the light of the first laser diode 11 reaching the etalon does not have common wavelengths with the further light of the second laser diode 12 reaching the etalon. And, of the light reflected back by the output coupler 40 and passed back through the etalon 30 the second long pass filter element 22 reflects back into the laser diode light of wavelengths shorter than the second cut-off wavelength W2. Of said back reflected and passed back through light, the first long pass filter element 21 reflects back into the laser diode light of wavelengths equal to or greater than second cut-off wavelength W2 but shorter than the first cut-off wavelength W1 thereby selecting one or more of the periodic peaks achievable by the etalon 30.

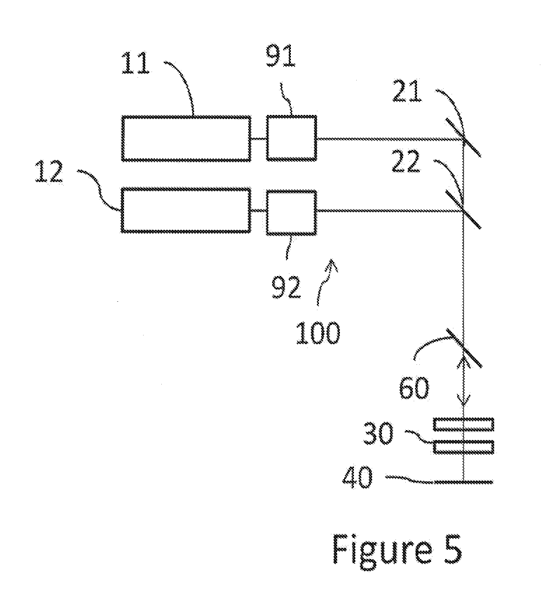

In order to select a single resonance mode of the etalon for feed back into the second laser source a further cut-off filter element 60 may be positioned between the second laser source element 20 and the second long pass filter element 22, as depicted in FIG. 4 which shows a third exemplary embodiment of the laser beam generating device according to the invention. Or, the further cut-off filter element 60 may be positioned between the second long pass filter element 22 and the etalon 30, as depicted in FIG. 5 showing a fourth exemplary embodiment of the laser beam generating device according to the invention. The each of the depicted further cut-off filter elements 60 is a long pass filter element having a shortest cut-off wavelength shorter than the first and the second cut-off wavelengths W1, W2.

In the depicted second, third and fourth exemplary embodiments, there is an optical elements 91, 92 for each of the laser diodes 11, 12 located in the external cavity for optimizing performance. But the optical elements 91, 92 are optional and each of these exemplary embodiments of the invention may be realized also with only one or none of the optical elements 91, 92.

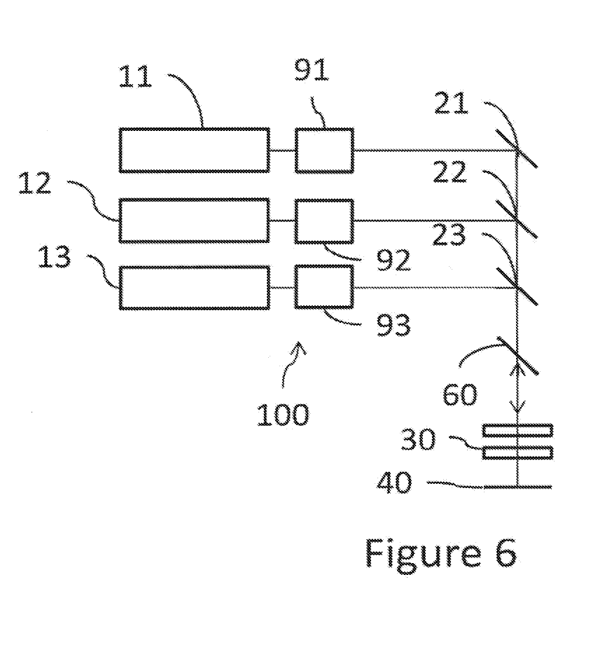

In FIG. 6, scaling is exemplarily depicted in a fifth exemplary embodiment of the laser beam generating device according to the invention. That is, for each laser source element to be further combined spectrally there is a cut-off filter element reflecting a part of the respectively irradiated light onto the common path on which the output coupler, the etalon and the cut-off filter elements for spectral combination are positioned. In FIG. 6 a third laser source element's 13 light is spectrally combined with the light of the first and the second laser source elements 11, 12 via a third long pass filter element 23 having a third cut-off wavelength W3 smaller than the second cut-off wavelength W2.

In FIG. 6, the further cut-off filter element 60 is present in the common path, too. In this embodiment the third cut-off wavelength has to be larger than the smallest cut-off wavelength.

In the depicted fifth exemplary embodiment, there is an optical element 91, 92, 93 for each of the laser diodes 11, 12, 13 located in the external cavity for optimizing performance. But the optical elements 91, 92, 93 are optional and this exemplary embodiments of the invention may also be realized with two, only one or none of the optical elements 91, 92, 93.

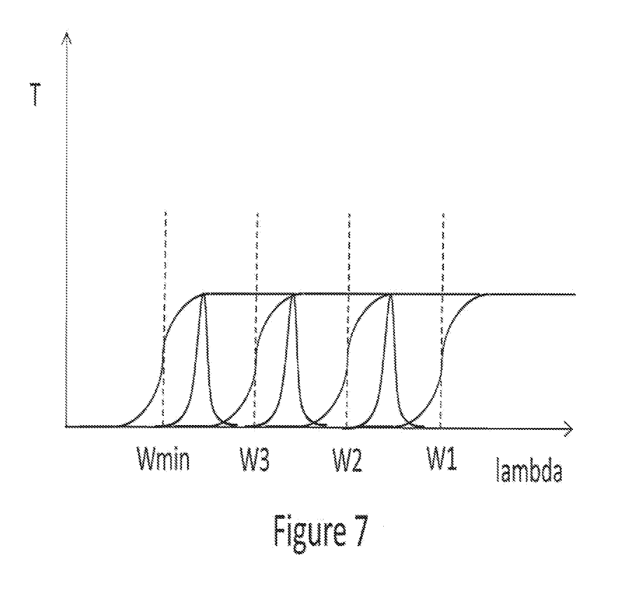

FIG. 7 schematically shows transmission T in dependency on wavelength lambda of the cut-off filter elements and the periodic filter element of the exemplary embodiment of FIG. 6. As exemplarily depicted in FIG. 7, between each pair of cut-of wavelengths of adjacent cut-off filter elements there is a peak of the periodic filter element.

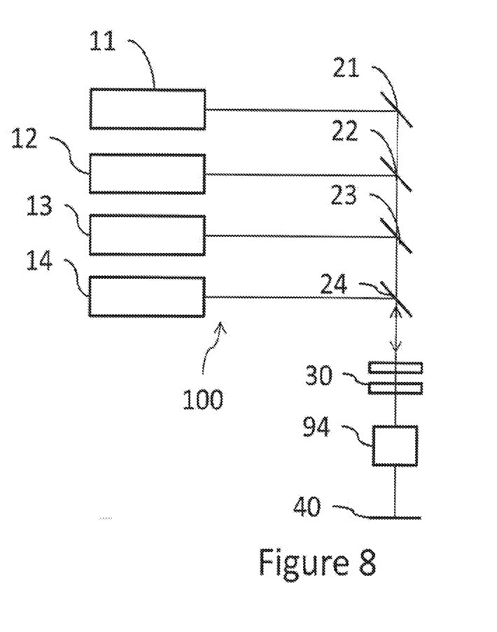

FIG. 8 shows a sixth exemplary embodiment of the laser beam generating device according to the invention. In FIG. 8 light irradiated by four different laser source elements 11, 12, 13, 14 is combined spectrally by means of the cut-off filter elements 21, 22, 23, 24. No further cut-off filter element is present in this example, but it may be added either between the fourth cut-off filter element 24 and either the fourth laser source element 24 or between the fourth cut-off filter element 24 and the etalon 30.

In the depicted sixth exemplary embodiment, there is an optical element 94 located in the external cavity between the etalon 30 and the output coupler 40 for optimizing performance. But the optical element 94 is optional. It may also be arranged between the etalon 30 and the fourth cut-off filter element 24.

Thus, the current invention provides means for spectral combination and frequency locking of n laser light sources through use of n cut-off filters and a single periodic filter. Advantageously a further cut-off filter can be used.

The exemplary embodiments described and depicted make use of long pass filter elements. In an analogous fashion short pass filter elements may be used. Further for each of the cut-off filter elements comprised or used according to the invention it can be decided individually whether it may be embodied by a long pass filter element or by a short pass filter element.

The periodic filter element may be placed in a joint external resonant cavity together with the cut-off filter elements thereby enabling automatic and simultaneous selection and multiplexing of oscillating wavelengths, each of a diode laser or a diode laser set oscillating on a single wavelength channel.

1. A laser beam generating device comprising at least one laser source element and an external cavity, the external cavity comprising an output coupler and a periodic filter element, wherein the laser beam generating device further comprises at least two cut-off filter elements each arranged on the light path between the laser source element and the periodic filter element, wherein the periodic filter element is arranged, on a light path from the laser source element to the output coupler (40), between the laser source element and the output coupler.

2. The laser beam generating device of claim 1, wherein the cut-off filter elements are long pass-filter elements having different cut-off wavelengths of which each allows radiation of wavelengths longer than a respective cut-off wavelength to pass, and at least reflect radiation of wavelengths shorter than the respective cut-off wavelength

3. The laser beam generating device of claim 2, the at least two long pass filter elements being cold mirrors.

4. The laser beam generating device of claim 3, the cold mirrors comprising dielectric coating layers. The laser beam generating device of claim 1, wherein the laser source element and the at least two cut-off filter elements being arranged on the light path such that light of the laser source element is irradiated onto a first of the at least two cut-off filter elements and reflected by the first cut-off filter element onto a second of the at least two cut-off filter elements through which it is transmitted.

6. The laser beam generating device of claim 5, further comprising a further laser source element which is arranged on the light path such that further light of the further laser source element is irradiated onto the second cut-off filter element and reflected by the second cut-off filter element such that it is kept in the cavity.

7. The laser beam generating device of claim 6 further comprising a further cut-off filter element arranged, either, on a further light path between the second cut-off filter element and the further laser source element, or, on the light path between the second cut-off filter element and the periodic filter element.

8. The laser beam generating device of claim 6, wherein the laser source element and the further laser source element are formed as laser diodes emitting light which diverges in a first direction faster than in a second direction perpendicular to the first direction, the laser diodes and the cut-off filter elements being arranged such that light of the laser diodes is superposed in the first direction.

9. The laser beam generating device of claim 8, further comprising collimating devices for collimating the light emitted by the laser diodes, the collimating devices collimating in the first direction and in the second direction.

10. The laser beam generating device of claim 1, wherein the laser diodes are single emitter laser diodes.

11. The laser beam generating device of claim 1, wherein the periodic filter element comprise two parallel plates placed spaced apart with air in between wherein sides of the plates facing each other have a reflectivity of 50%.

12. A method for adjusting a wavelength of a laser beam using a laser beam generating device comprising at least one laser source element and an external cavity, the external cavity comprising an output coupler and a periodic filter element, wherein the laser beam generating device further comprises at least two cut-off filter elements each arranged on the light path between the laser source element and the periodic filter element, wherein the periodic filter element is arranged, on a light path from the laser source element to the output coupler (40), between the laser source element and the output coupler, wherein the periodic filter element comprises an etalon, the method comprising adjusting the wavelength by turning the etalon around an axis.
